(19) United States
(12) Patent Application Publication
(10) Pub. No.: US 2015/0055105 A1
(43) Pub. Date: Feb. 26, 2015

(54) EXPOSURE APPARATUS, EXPOSURE METHOD, AND EXPOSURE PROGRAM

(71) Applicant: Kabushiki Kaisha Toshiba, Minato-ku (JP)

(72) Inventors: Koji IWANAKA, Yokkaichi-shi (JP); Taisuke MIWA, Yokkaichi-shi (JP)

(73) Assignee: Kabushiki Kaisha Toshiba, Minato-ku (JP)

(21) Appl. No.: 14/197,726

(22) Filed: Mar. 5, 2014

(30) Foreign Application Priority Data
Aug. 23, 2013 (JP) 2013-173912

(51) Int. Cl. G03F 7/20

(52) U.S. Cl. CPC G03F 7/7055
USPC 355/55

(57) ABSTRACT

According to one embodiment, a scan control unit, a focus control unit, and a focus control region setting unit are provided. The scan control unit performs scan control of exposure light on an XY plane, the focus control unit performs focus control of the exposure light, and the focus control region setting unit sets a focus control region such that focus control ranges in an X-axis direction and in a Y-axis direction on the XY plane are different each other.

### CROSS-REFERENCE TO RELATED APPLICATIONS

This application is based upon and claims the benefit of priority from Japanese Patent Application No. 2013-173912, filed on Aug. 23, 2013; the entire contents of which are incorporated herein by reference.

### FIELD

Embodiments described herein relate generally to an exposure apparatus, an exposure method, and an exposure program.

### BACKGROUND

In an exposure apparatus, focus control is performed in order to deal with a height difference of a wafer. At this time, a focus control region is set to an inner side from a wafer edge by a fixed distance. That is, typically, a large height difference (step) may be caused in the vicinity of the wafer edge due to an influence of a semiconductor manufacturing process. Therefore, processing of excluding a fixed distance from the wafer edge from an object subject to the focus control is deliberately performed. In this case, the focus control region is a perfect circle.

### BRIEF DESCRIPTION OF THE DRAWINGS

FIG. 1 is a perspective view illustrating a schematic constitution of an exposure apparatus according to an embodiment;

FIG. 2 is a plan view illustrating an example of a focus control region in the exposure apparatus according to the embodiment;

FIG. 3 is a diagram illustrating an example of a method of setting the focus control region in the exposure apparatus according to the embodiment;

FIG. 4 is a perspective view illustrating a method of performing the focus control in the exposure apparatus according to the embodiment;

FIG. 5 is a plan view illustrating a relationship between the focus control region and a chip region in the exposure apparatus according to the embodiment; and

FIG. 6 is a block diagram illustrating a hardware constitution example of an exposure control unit of FIG. 1.

### DETAILED DESCRIPTION

According to an embodiment, a scan control unit, a focus control unit, and a focus control region setting unit are provided. The scan control unit performs scan control of exposure light on an XY plane. The focus control unit performs focus control of the exposure light. The focus control region setting unit sets the focus control region such that focus control ranges in an X-axis direction and in a Y-axis direction on the XY plane are different each other.

Hereinafter, an exposure apparatus according to embodiments will be described in detail with reference to the appended drawings. Note that the present invention is not limited by these embodiments.

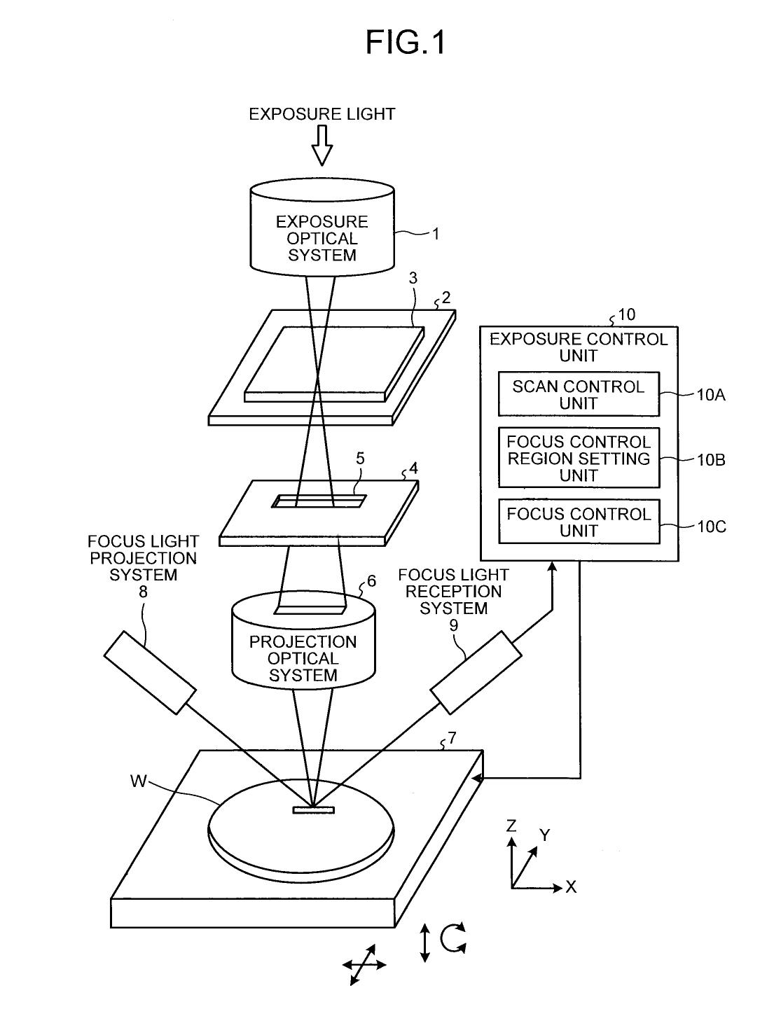

FIG. 1 is a perspective view illustrating a schematic constitution of an exposure apparatus according to an embodiment.

In FIG. 1, the exposure apparatus includes an exposure optical system 1, a reticle stage 2, a slit plate 4, a projection optical system 6, a wafer stage 7, a focus light projection system 8, a focus light reception system 9, and an exposure control unit 10.

The wafer stage 7 holds a wafer W. Note that the wafer stage 7 can be moved in the X-axis direction, the Y-axis direction, and a Z-axis direction. In addition, the wafer stage 7 can be tilted with respect to the X-axis direction. The reticle stage 2 holds a reticle 3. The exposure optical system 1 leads the exposure light to the projection optical system 6 through the reticle 3. Note that, as the exposure light, for example, ultraviolet light can be used. The slit plate 4 shapes the exposure light in a slit manner. Note that a slit 5 is formed in the slit plate 4. The projection optical system 6 projects, on the wafer W, the exposure light formed in a slit manner. The focus light projection system 8 projects focus light on the wafer W. The focus light reception system 9 receives the focus light projected on the wafer W. Note that, as the focus light, halogen light can be used. The exposure control unit 10 controls the exposure light on a surface of the wafer W. Here, the exposure control unit 10 includes a scan control unit 10A, a focus control region setting unit 10B, and a focus control unit 10C. The scan control unit 10A performs scan control of the exposure light on the XY plane. The focus control region setting unit 10B sets the focus control region such that the focus control ranges are different in the X-axis direction and in the Y-axis direction on the XY plane. The focus control unit 10C performs focus control of the exposure light in the focus control region.

When exposure is performed on the surface of the wafer W, the wafer W is held on the wafer stage 7. At this time, a resist film can be formed on the entire surface of the wafer W. Further, the reticle 3 is held on the reticle stage 2.

When the exposure light is incident on the exposure optical system 1, the exposure light is led to the slit plate 4 through the reticle 3, and is formed in a slit manner. The exposure light formed in the slit manner is then projected on the wafer W through the projection optical system 6. At this time, a longitudinal direction of the slit 5 is set to the X-axis direction. The direction of travel of the exposure light on the wafer W is then set to the Y-axis direction by the wafer stage 7 being moved in the Y-axis direction. When the exposure light is scanned from one end to the other end of the wafer W in the Y-axis direction, the direction of travel of the exposure light on the wafer W is set to the Y-axis direction by the wafer stage 7 being moved to be folded in the Y-axis direction after being moved in the X-axis direction by one shot.

Further, in the focus control region setting unit 10B, the focus control region is set such that the focus control range in the Y-axis direction on the XY plane is larger than that in the X-axis direction on the XY plane. The focus control region can be set in an ellipse, for example.

A focusing state on the wafer W is determined by the focus light projected on the wafer W being sent to the exposure control unit 10 through the focus light reception system 9. Then in the focus control unit 10C, the exposure light is subject to the focus control in the focus control region by the wafer stage 7 being driven to focus on the wafer W. At this time, with respect to the X-axis direction, a focus position can be adjusted by the wafer stage 7 being tilted with respect to the X-axis direction. With respect to the Y-axis direction, the focus position can be adjusted by the wafer stage 7 being moved up and down.

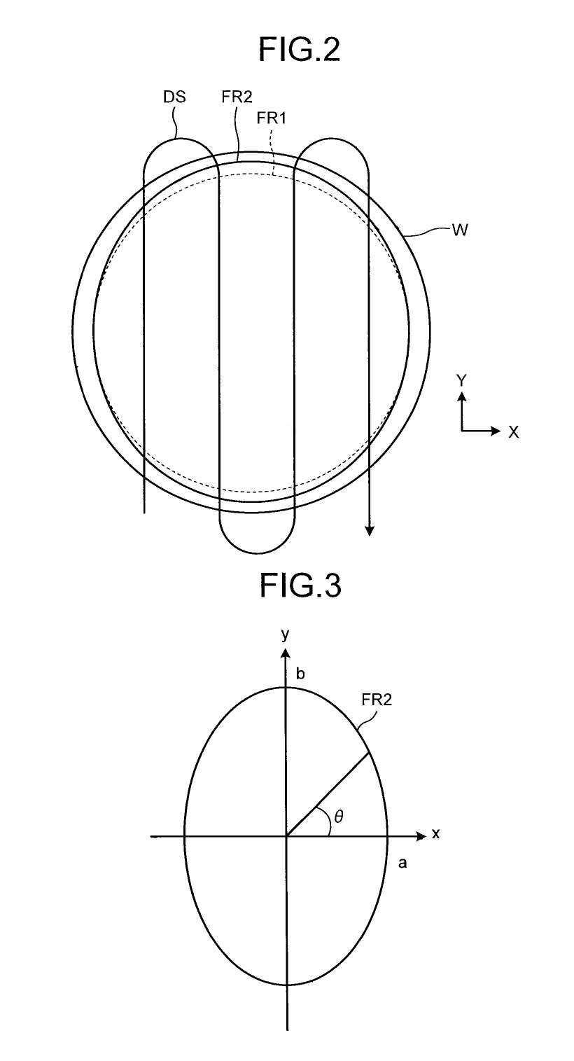

FIG. 2 is a plan view illustrating an example of a focus control region in an exposure apparatus according to an embodiment.

In FIG. 2, a focus control region FR1 is set to an inner side from an edge of the wafer W by a fixed distance, and the shape of the focus control region FR1 is a perfect circle. Meanwhile, a focus control region FR2 is set such that the region in the Y-axis direction on the XY plane is larger than that in the X-axis direction on the XY plane, and the shape of the focus control region FR2 can be, for example, an ellipse. The entire surface of the wafer W is then exposed by the exposure light being scanned on the XY plane along a scanning direction DS. At this time, the direction of travel of the exposure light on the wafer W is set to the Y-axis direction by movement of the exposure light in the X-axis direction being performed outside the wafer W. Note that the focus light is emitted along the scanning direction DS before the start of scanning of the exposure light, and the focusing state on the wafer W is measured in advance.

FIG. 3 is a diagram illustrating an example of a method of setting a focus control region in an exposure apparatus according to an embodiment.

In FIG. 3, when the shape of the focus control region FR2 is an ellipse, an orbit (x, y) of a border of the focus control region FR2 can be given by (x, y)=(a*cos θ, b*sin θ) where an angle made by a line segment connecting a point on the orbit and the center (0, 0) of the ellipse, and the X axis is θ, an intersection point of the ellipse and the X axis is (a, 0), and an intersection point of the ellipse and the Y axis is (0, b).

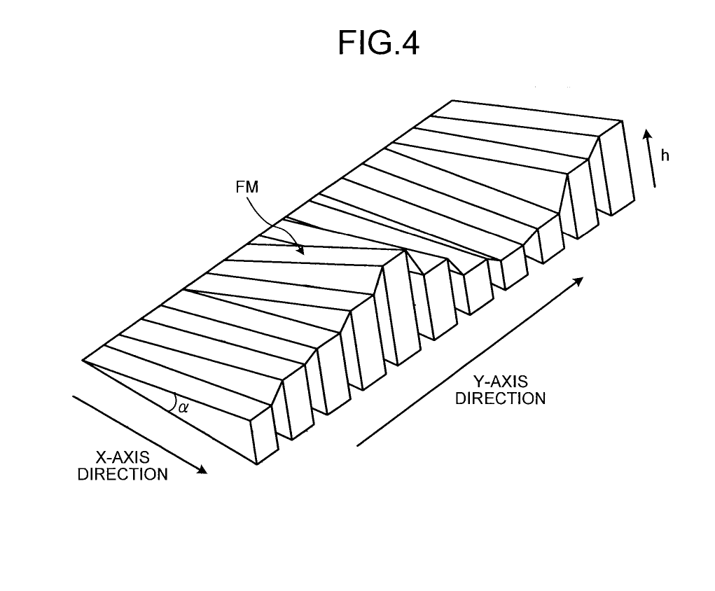

FIG. 4 is a perspective view illustrating a method of performing focus control in an exposure apparatus according to an embodiment.

In FIG. 4, in the exposure apparatus of FIG. 1, the exposure light formed in a slit manner is scanned in the Y-axis direction on the wafer W in each shot. At this time, with respect to the X-axis direction, the focus position is adjusted by the wafer stage 7 being tilted by an angle α with respect to the X-axis direction. With respect to the Y-axis direction, the focus position is adjusted by the wafer stage 7 being moved up and down by a height h.

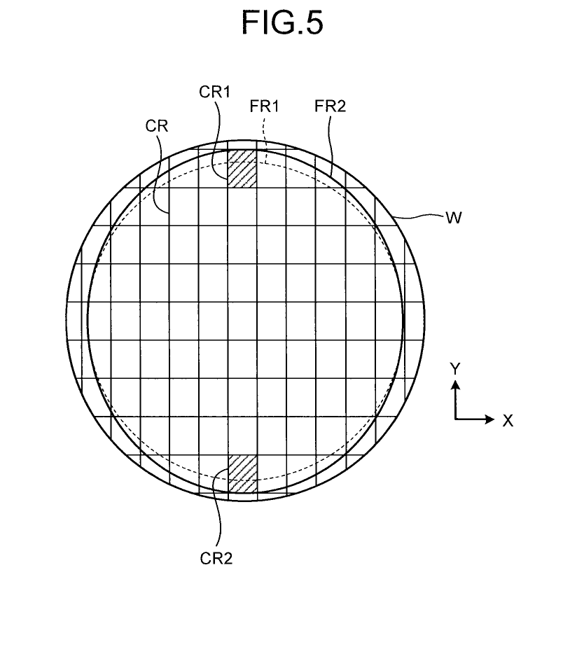

FIG. 5 is a plan view illustrating a relationship between a focus control region and a chip region in an exposure apparatus according to an embodiment.

In FIG. 5, in exposure processing, the same pattern is formed in each chip region CR that is obtained by dividing of the wafer W. At this time, a chip region CR protruding from the focus control regions FR1 and FR2 cannot be used as a product. As illustrated in FIG. 2, focus measuring is performed to reciprocate on the wafer W in the Y-axis direction. In the focus control in the Y-axis direction in the exposure processing, the stage is controlled in two directions: the direction of travel in the Y-axis direction and the up and down direction. Meanwhile, the focus control in the X-axis direction in the exposure processing is controlled by only the tilt of the stage. Therefore, the focus controllability is higher in the Y-axis direction than in the X-axis direction. In the present embodiment, focusing can easily follow in the Y-axis direction. Therefore, the focus control region is changed to the FR2 (ellipse) in which the region FR1 is expanded in the Y-axis direction, instead of the FR1 (perfect circle). Even if a large step occurs in the vicinity of the wafer edge in the Y-axis direction, the focus control can be relatively easily performed. Accordingly, the number of chips that can be obtained from the wafer W can be increased. Note that if the focus control region FR1 is expanded in the X-axis direction and when a large step occurs in the vicinity of the wafer edge in the X-axis direction, the focus control in the X-axis direction is not good and therefore focusing cannot follow the step.

Note that, in the above-described embodiment, a method in which the shape of the focus control region FR2 is an ellipse has been employed as an example. However, the focus control region FR2 may be formed into a cocoon shape, a barrel shape, or a polygon.

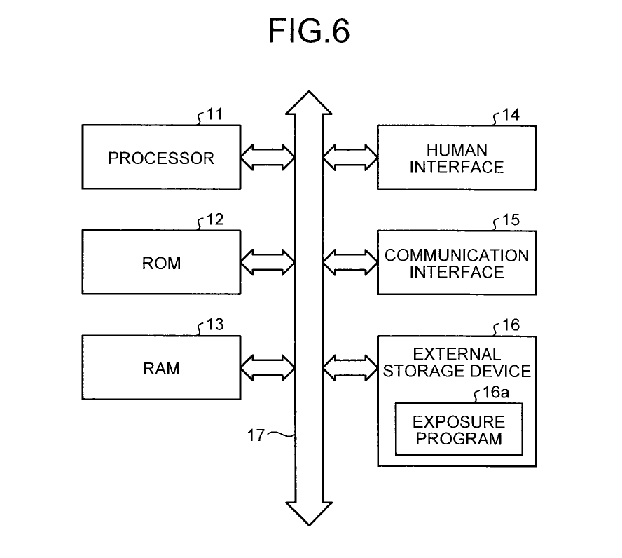

FIG. 6 is a block diagram illustrating a hardware constitution example of the exposure control unit of FIG. 1.

In FIG. 6, the exposure control unit 10 can include a processor 11 that includes a CPU, a ROM 12 that stores fixed data, a RAM 13 that provides the processor 11 with a work area and the like, a human interface 14 that intermediate between a human and a computer, a communication interface 15 that provides a communication means between the exposure apparatus and an outside, and an external storage device 16 that stores a program for operating the processor 11 and various types of data, and the processor 11, the ROM 12, the RAM 13, the human interface 14, the communication interface 15, and the external storage device 16 are connected through a bus 17.

Note that, as the external storage device 16, for example, a magnetic disk such as a hard disk, an optical disk such as a DVD, or a portable semiconductor storage device such as a USB memory or a memory card can be used. Further, as the human interface 14, for example, a keyboard, a mouse, or a touch panel as an input interface, and a display, or a printer as the output interface can be used. Further, as the communication interface 15, for example, a LAN card, a modem, or a router for connecting to the Internet or a LAN can be used. Here, an exposure program 16a that causes a computer to execute exposure control is installed in the external storage device 16.

When the exposure program 16a is executed in the processor 11, the focus control region is set such that the focus control ranges in the X-axis direction and in the Y-axis direction on the XY plane are different. The exposure light is then subject to focus control in the focus control region while being subjected to scan control on the XY plane.

Note that the exposure program 16a executed by the processor 11 may be stored in the external storage device 16 in advance and read to the RAM 13 at the execution of the program, or may be stored in the ROM 12 in advance. Alternatively, the exposure program 16a may be obtained through the communication interface 15. Further, the exposure program 16a may be executed by a stand-alone computer, or may be executed by a cloud computer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An exposure apparatus comprising:
a scan control unit configured to perform scan control of exposure light on an XY plane;
a focus control unit configured to perform focus control of the exposure light; and
a focus control region setting unit configured to set a focus control region such that focus control ranges in an X-axis direction and in a Y-axis direction on the XY plane are different each other.

2. The exposure apparatus according to claim 1, comprising:
a wafer stage configured to hold a wafer;
a slit plate configured to form the exposure light in a slit manner; and
a projection optical system configured to project the exposure light formed in a slit manner on the wafer.

3. The exposure apparatus according to claim 2, wherein the scan control unit performs scan control of the exposure light projected on the wafer on the XY plane, the focus control region setting unit sets the focus control region such that the focus control range in the Y-axis direction on the XY plane is larger than the focus control range in the X-axis direction on the XY plane, and the focus control unit performs focus control of the exposure light projected on the wafer in the focus control region.

4. The exposure apparatus according to claim 3, wherein a longitudinal direction of the slit is set to the X-axis direction,
a scan direction of the exposure light on the wafer is set to the Y-axis direction,
with respect to the X-axis direction, a focus position is adjusted by the wafer stage being tilted with respect to the X-axis direction, and
with respect to the Y-axis direction, a focus position is adjusted by the wafer stage being moved up and down.

5. The exposure apparatus according to claim 4, wherein the focus control region setting unit sets the focus control region in an ellipse.

6. The exposure apparatus according to claim 2, comprising:
a focus light projection system configured to project focus light on the wafer; and
a focus light reception system configured to receive the focus light projected on the wafer.

7. The exposure apparatus according to claim 6, wherein the focus light is emitted before start of scanning of the exposure light, and a focusing state on the wafer is measured in advance.

8. An exposure method comprising:
setting a focus control region such that focus control ranges in an X-axis direction and in an Y-axis direction on an XY plane are different each other; and
performing focus control of exposure light in the focus control region while performing scan control of the exposure light on the XY plane.

9. The exposure method according to claim 8, wherein the focus control region is set such that the focus control range in the Y-axis direction on the XY plane is larger than the focus control range in the X-axis direction on the XY plane.

10. The exposure method according to claim 9, comprising:
holding a wafer on a wafer stage;
forming the exposure light in a slit manner; and
projecting the exposure light formed in a slit manner on the wafer.

11. The exposure method according to claim 10, wherein a longitudinal direction of the slit is set to the X-axis direction,
a scan direction of the exposure light on the wafer is set to the Y-axis direction,
with respect to the X-axis direction, a focus position is adjusted by the wafer stage being tilted with respect to the X-axis direction, and
with respect to the Y-axis direction, a focus position is adjusted by the wafer stage being moved up and down.

12. The exposure method according to claim 9, wherein the focus control region is set in an ellipse.

13. The exposure method according to claim 10, comprising:
projecting focus light on the wafer; and
receiving the focus light projected on the wafer.

14. The exposure method according to claim 13, wherein the focus light is emitted before start of scanning of the exposure light, and a focusing state on the wafer is measured in advance.

15. An exposure program for causing a computer to execute:
setting a focus control region such that focus control ranges in an X-axis direction and in an Y-axis direction on an XY plane are different each other; and
performing focus control of exposure light in the focus control region while performing scan control of exposure light on an XY plane.

16. The exposure program according to claim 15, wherein the focus control region is set such that the focus control range in the Y-axis direction on the XY plane is larger than the focus control range in the X-axis direction on the XY plane.

17. The exposure program according to claim 16, wherein a longitudinal direction of a slit that forms the exposure light in a slit manner is set to the X-axis direction,
a scan direction of the exposure light on a wafer held on a wafer stage is set to the Y-axis direction,
with respect to the X-axis direction, a focus position is adjusted by the wafer stage being tilted, and
with respect to the Y-axis direction, a focus position is adjusted by the wafer stage being moved up and down.

18. The exposure program according to claim 16, wherein the focus control region is set in an ellipse.

19. The exposure program according to claim 10, comprising:
projecting focus light on the wafer, and
receiving the focus light projected on the wafer.

20. The exposure program according to claim 19, wherein the focus light is emitted before start of scanning of the exposure light, and a focusing state on the wafer is measured in advance.
